(19) United States
(12) Patent Application Publication
(10) Pub. No.: US 2017/0093118 A1
(43) Pub. Date: Mar. 30, 2017

(54) EXTERNAL CAVITY TYPE TUNABLE WAVELENGTH LASER MODULE FOR TO-CAN PACKAGING

(71) Applicant: CHEM OPTICS INC., Daejeon (KR)

(72) Inventors: Hak Kyu LEE, Seoul (KR); Joon Oh PARK, Daejeon (KR); Jun Kyu SEO, Daejeon (KR); Jang Uk SHIN, Daejeon (KR)

(21) Appl. No.: 15/311,798

(22) PCT Filed: May 20, 2015
(86) PCT No.: PCT/KR2015/005062

§ 371 Date: Nov. 16, 2016

(30) Foreign Application Priority Data
May 20, 2014 (KR) 10-2014-0060578
May 19, 2015 (KR) 10-2015-0069933

(51) Int. Cl. H01S 3/131; H01S 3/139; H01S 5/14

(52) U.S. Cl. CPC H01S 3/1317; H01S 5/141; H01S 3/139

(57) ABSTRACT

Provided is a tunable wavelength laser module including: an external cavity type light source generating broadband light; an optical waveguide; a Bragg grating formed in the optical waveguide; a heater provided above the optical waveguide in which the Bragg grating is formed and adjusting a reflection band of the Bragg grating by a thermo-optic effect; a direction change waveguide region changing direction of optical signals obtained by the adjusted reflection band of the Bragg grating, by a predetermined angle; a 45-degree reflection part transmitting some of the optical signals direction-changed by the direction change waveguide region and escaping from the optical waveguide therethrough and reflecting the others of the optical signals in a vertical upward direction thereby; and a lens making the optical signals reflected in the vertical upward direction by the 45-degree reflection part collimated light or convergent light.

### TECHNICAL FIELD

The present invention relates to an external cavity type tunable wavelength laser module for TO-CAN packaging capable of tuning a wavelength in a wide wavelength region, being cheap, and having high reliability.

### BACKGROUND ART

A wavelength division multiplexing (WMD) optical communication technology, which is a technology currently applied to most of backbone networks and metro-networks, is a technology of performing wavelength-division-multiplexing on an optical line consisting of one optical fiber to transmit a plurality of high speed signals. Recently, in a transmission network in a WDM scheme, an effort to increase flexibility of the transmission network and decrease an inventory amount and an operation cost by using a tunable wavelength laser module has increased.

Among tunable wavelength laser modules, a laser module using a distributed feed back (DFB) structure has been developed and commercialized. However, since the DFB laser module has a narrow tunable wavelength range of 10 nm or less, three or four sets of tunable wavelength DFB laser modules should be used in order to support all wavelengths in a C-band (1535 nm to 1565 nm). In addition, a tunable wavelength transponder using the DBF laser module has a light source that is expensive and should include a multi-channel transponder for a backup purpose, such that it does not provide an efficient solution to a network operator in terms of decreasing in an inventory amount. Therefore, there is a need to develop an external cavity type tunable wavelength laser module capable of singly tuning all required wavelengths in a WDM band (for example, the C-band).

FIG. 1 is a plan view of a butterfly type package, which is an external cavity type tunable wavelength laser module according to the related art, and FIG. 2 is a side view of the butterfly type package, which is the external cavity type tunable wavelength laser module according to the related art. In more detail, FIG. 2 is a configuration diagram of the butterfly type package in which a laser diode chip and an optical waveguide are butt-coupled to each other. An XMD type package having a size smaller than that of the butterfly type package basically has a configuration similar to the configuration of the butterfly type package.

The external cavity type tunable wavelength laser module according to the related art illustrated in FIGS. 1 and 2 may be configured to include a laser diode chip for a light source positioned at an upper portion of a chip stem 11, an optical waveguide 20 in which a Bragg grating 30 for tuning a wavelength is formed, a heater 40 provided on the optical waveguide 20, a beam splitter 50 reflecting some of optical signals output from the optical waveguide 20 thereby and transmitting the others of the optical signals therethrough, a lens 60 focusing the optical signals transmitted through the beam splitter 50, a photodiode 70 measuring power of the optical signals reflected by the beam splitter 50, a temperature sensor 81 setting an operation temperature of the external cavity type tunable wavelength laser module regardless of an external temperature environment, and a thermoelectric cooler 82.

However, in the case in which the external cavity type tunable wavelength laser module is configured as described above, a volume of the optical waveguide 20 including the Bragg grating 30 is large, such that an entire volume of the external cavity type tunable wavelength laser module cannot but become large. Therefore, a large cost cannot but be required for packaging the external cavity type tunable wavelength laser module.

Generally, a transistor outline (TO)-CAN package is manufactured at a cost cheaper than that of the butterfly type package or the XMD type package and has a volume smaller than that of the butterfly type package or the XMD type package. Therefore, the TO-CAN package has been widely used in an optical module for communication. However, since an output direction of optical signals should be a vertical upward direction to a TO stem surface on which optical elements are put for the purpose of TO-CAN packaging, a moving direction of optical signals emitted in parallel with the TO stem surface should be changed into the vertical upward direction.

Meanwhile, an optical waveguide type polymer tunable wavelength filter technology using a Bragg grating has been first implemented in “Tunable Wavelength Filters with Bragg Gratings in Polymer waveguides” pp. 2543-2545 of Applied Physics Letters, November (no 2), 1998, by M. Oh, etc., and a technology related to the optical waveguide type polymer tunable wavelength filter technology using a Bragg grating has been registered as U.S. Pat. No. 6,303,040.

### DISCLOSURE

### Technical Problem

An object of the present invention is to provide an external cavity type tunable wavelength laser module having an optical waveguide including a Bragg grating and designed in a structure in which a moving direction of optical signals may be changed, rather than a linear structure, in order to TO-CAN-package optical elements constituting the external cavity type tunable wavelength laser module.

### Technical Solution

In one general aspect, an external cavity type tunable wavelength laser module includes: an external cavity type light source generating broadband light; an optical waveguide to which the broadband light output from the light source is input; a Bragg grating formed in the optical waveguide; a heater provided above the optical waveguide in which the Bragg grating is formed and adjusting a reflection band of the Bragg grating by a thermo-optic effect; a direction change waveguide region changing direction of optical signals obtained by the adjusted reflection band of the Bragg grating, by a predetermined angle; a 45-degree reflection part transmitting some of the optical signals direction-changed by the direction change waveguide region and escaping from the optical waveguide therethrough and reflecting the others of the optical signals in a vertical upward direction thereby; and a lens making the optical signals reflected in the vertical upward direction by the 45-degree reflection part collimated light or convergent light.

The direction change waveguide region may be configured to direction-change the optical signals obtained by adjusting the reflection band of the Bragg grating, by 180 degrees.

The external cavity type tunable wavelength laser module may further include a photodiode measuring power of the optical signals transmitted through the 45-degree reflection part.

The external cavity type tunable wavelength laser module may further include: a temperature sensor and a thermoelectric cooler; and a temperature control device electrically connected to the heater, the temperature sensor, and the thermoelectric cooler to receive a signal sensed from the temperature sensor, thereby adjusting heat generation of the heater and heat absorption of the thermoelectric cooler.

The temperature sensor may be provided above the optical waveguide, and the thermoelectric cooler may be provided below the optical waveguide.

The optical waveguide may be a polymer optical waveguide made of a polymer.

The Bragg grating may be a polymer Bragg grating made of a polymer, and the polymers forming the optical waveguide and the Bragg grating may include a halogen element, and include a functional group cured by ultraviolet rays or heat.

A thermo-optic coefficient of the polymers forming the optical waveguide and the Bragg grating may be −9.9×10⁻⁴ to −0.5×10⁻⁴⁰ C⁻¹.

A geometric structure of the optical waveguide may be a rib structure, a ridge structure, an inverted rib structure, an inverted ridge structure, or a channel structure.

### Advantageous Effects

According to the present invention, the optical waveguide in which the Bragg grating is formed is designed in a structure in which the moving direction of the optical signals is changed, such that a volume of the external cavity type tunable wavelength laser module may be reduced, thereby making it possible to achieve TO-CAN packaging.

In addition, optical elements constituting the external cavity type tunable wavelength laser module according to the present invention are bonded to a planar optical waveguide, such that a complicated process such as an aligning process, or the like, is removed to facilitate a work, thereby making it possible to contribute to improvement of productivity.

Further, a standardized small TO-CAN package is used, thereby making it possible to perform a wavelength turning function that is stable and has high reproducibility and reliability.

### DESCRIPTION OF DRAWINGS

FIG. 1 is a plan view of a butterfly type package, which is an external cavity type tunable wavelength laser module according to the related art.

FIG. 2 is a side view of the butterfly type package, which is the external cavity type tunable wavelength laser module according to the related art.

FIG. 3 is a plan view of an external cavity type tunable wavelength laser module for TO-CAN packaging according to an exemplary embodiment of the present invention.

FIG. 4 is a side view of the external cavity type tunable wavelength laser module for TO-CAN packaging according to an exemplary embodiment of the present invention.

FIG. 5 is a view illustratively illustrating a structure of an optical waveguide and a position at which a Bragg grating is formed in the optical waveguide in the external cavity type tunable wavelength laser module for TO-CAN packaging according to the present invention.

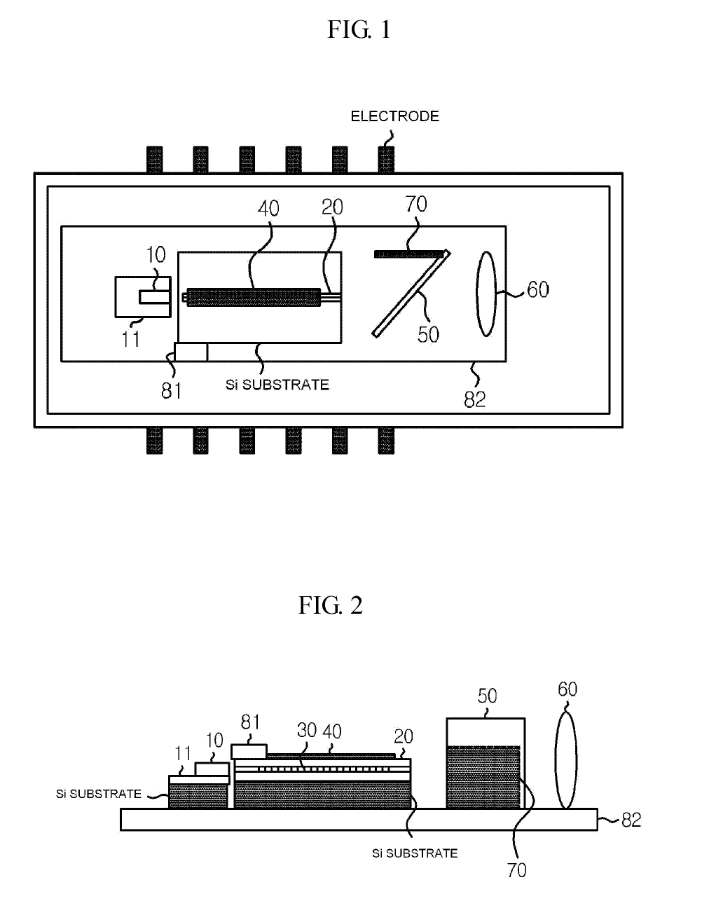

### BEST MODE

Hereinafter, an external cavity type tunable wavelength laser module for TO-CAN packaging according to the present invention will be described in detail with reference to the accompanying drawings. The accompanying drawings are provided by way of example in order to sufficiently transfer the spirit of the present invention to those skilled in the art, and the present invention is not limited to the accompanying drawing provided below, but may be implemented in another form.

Technical terms and scientific terms used in the present specification have the general meaning understood by those skilled in the art to which the present invention pertains unless otherwise defined, and a description for the known function and configuration unnecessarily obscuring the gist of the present invention will be omitted in the following description and the accompanying drawings.

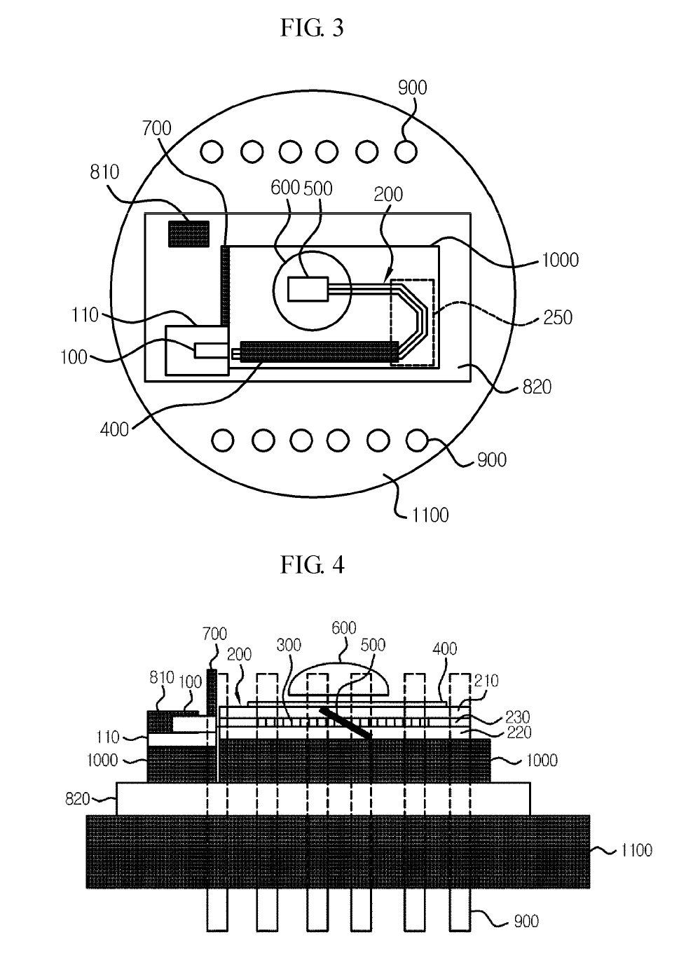

FIG. 3 is a plan view of an external cavity type tunable wavelength laser module for TO-CAN packaging according to an exemplary embodiment of the present invention, and FIG. 4 is a side view of the external cavity type tunable wavelength laser module for TO-CAN packaging according to an exemplary embodiment of the present invention.

The present invention provides a tunable wavelength laser module outputting required optical signals to the outside by adjusting a wavelength band reflected by a Bragg grating (that is, a reflection band of the Bragg grating) using a thermo-optic effect of an optical waveguide (more preferably, an optical waveguide made of a polymer), and is characterized in that a volume of the tunable wavelength laser module is reduced for the purpose of TO-CAN packaging.

To this end, the tunable wavelength laser module according to the present invention may be configured to include an external cavity type light source 100 generating broadband light, an optical waveguide 200 to which the broadband light output from the light source 100 is input, a Bragg grating 300 formed in the optical waveguide 200, a heater 400 provided above the optical waveguide 200 in which the Bragg grating 300 is formed and adjusting a reflection band of the Bragg grating 300 by a thermo-optic effect, a direction change waveguide region 250 changing direction of optical signals obtained by the adjusted reflection band of the Bragg grating 300, by a predetermined angle,

a 45-degree reflection part 500 transmitting some of the optical signals direction-changed by the direction change waveguide region 250 and escaping from the optical waveguide therethrough and reflecting the others of the optical signals in a vertical upward direction thereby, and a lens 600 making the optical signals reflected in the vertical upward direction by the 45-degree reflection part 500 collimated light or convergent light.

The external cavity type light source 100 may be a semiconductor optical amplifier or a semiconductor laser diode chip generating the broadband light. In this case, an emitting surface of the light source may be anti-reflection coated at a reflectivity of 1% or less, and an opposite surface to the emitting surface may be high-reflection-coated at a reflectivity of 80% or more.

In the case in which the light source 100 is the semiconductor laser diode chip for broadband wavelength oscillation, the semiconductor laser diode chip has a structure including an active layer in which light is generated, a current preventing layer, and p-metal and n-metal layers, and may be made of a combination of elements of Groups III to V or a combination of elements of Groups II to IV, such as InGaAsP, InGaAlAs, InAlAs, or the like, on an InP substrate, and the active layer may have a multi-quantum well or bulk active structure.

An optical coupled lens (not illustrated) may be provided between the light source 100 and the optical waveguide 200. In this case, the optical coupled lens condenses the light output from the light source 100 to allow the light source 100 to be butt-coupled to the optical waveguide 200 in which the Bragg grating 300 is formed. In more detail, the optical waveguide 200 includes an upper cladding 210 and a lower cladding 220 inducing total reflection and a core 230 in which transmission of the light is generated, and the light condensed by the optical coupled lens may be input to the core 230 of the optical waveguide 200. Meanwhile, the light source 100 may be provided on a chip stem 110 for physically supporting the light source 100.

The optical waveguide 200 may be a path having one end to which the broadband light output from the light source 100 is input and the other end from which the optical signals obtained by the Bragg grating 300 are output. The optical waveguide 200 may be provided on and supported by a substrate 1000. In this case, the substrate 1000 may be a silicon substrate, a polymer substrate, a glass substrate, or the like.

The optical waveguide 200 includes the claddings 210 and 220 and the core 230 surrounded by the claddings 210 and 220, and a refractive index of the core 230 is higher than those of the claddings 210 and 220, such that the light incident to the core 230 is totally reflected on boundary surfaces between the core 230 and the claddings 210 and 220 depending on an incident angle thereof.

The Bragg grating 300 may be manufactured by forming grooves having predetermined periods in the claddings 210 and 220 or the core 230 of the optical waveguide 200 in a moving direction of the light, and empty spaces (air) of the grooves may form the Bragg grating 300 or a material such as silicon oxide or polysilicon may be filled in the grooves to form the Bragg grating 300.

The grooves forming the Bragg grating 300 and having the predetermined periods apply periodic perturbation to a refractive index of the optical waveguide 200 through which the light moves, thereby reflecting a wavelength determined by an interval between the grooves forming the Bragg grating. In addition, an optical signal having a central wavelength of the reflection band of the Bragg grating 300 is generated by resonance that the wavelength reflected by the Bragg grating 300 is re-input to the emitting surface of the light source 100.

This will be described in more detail. The wavelength λ reflected by the Bragg grating 300 is determined by a grating Equation represented by the following Equation 1:

mλ=2n [symbol] . [Equation 1]

Here, m is an odd number representing an order of the Bragg grating, such as 1, 3, 5, 7, or the like, n is an effective refractive index of the optical waveguide, and [symbol] is a period of the grooves of the Bragg grating.

An optical signal having a specific wavelength, satisfying a Bragg condition by the Bragg grating 300 (for example, an optical signal having a central wavelength of λi) among optical signals having multiple wavelengths and having a broadband, incident to one end of the optical waveguide 200 (for example, optical signals having central wavelengths of λ1 to λn) is partially reflected to return to one end of the optical waveguide 200, and optical signals having the other wavelengths may be output to the other end of the optical waveguide 200. In this case, strength of light of the optical signal reflected to one end of the optical waveguide 200 is amplified in the light source (for example, the semiconductor laser diode chip) 100, and the optical signal of which the strength of the light is fed back to the optical waveguide 200 in which the Bragg grating 300 is formed. As a result, laser having a narrow line width and having the central wavelength of λi is oscillated and is output to the other end of the optical waveguide 200.

Meanwhile, a change in a Bragg reflection wavelength depending on a temperature is induced as represented by the following Equation 2 from the above Equation 1:

m·dλ/dT=2d(n [symbol] )/dT=λ₀(1/n·dn/dT+1/ [symbol] ·d [symbol] /dT). [Equation 2]

Here, m and n are the same as those of the above Equation 1, and λ₀ is an initial reflection wavelength. That is, a change amount of the reflection wavelength depending on the temperature is in proportion to the sum of a change amount of an effective refractive index depending on the temperature and a change amount of the period of the grooves forming the Bragg grating. For example, when a silicon waveguide Bragg grating of which a grating order (m) is 1 and an initial wavelength (λ₀) is 1550 nm is assumed, it may be appreciated that a change in the reflection wavelength depending on the temperature is 0.085 nm/K and a temperature for changing 12 nm corresponding to 16 channels of an interval of 100 GHz is about 142K. In the above example, a thermo-optic coefficient (Δn/ΔT) of silicon was 1.9×10⁻⁴/K, and a change of the period by the temperature was ignored.

In order to adjust the reflection band of the Bragg grating 300 using the thermo-optic effect as described above, it is preferable that the heater 400 is provided on the optical waveguide 200 in which the Bragg grating 300 is formed.

The heater 400 generates Joule heat by a predetermined electrical signal applied thereto to change a temperature of the optical waveguide 200 in which the Bragg grating 300 is formed, and adjusts a wavelength band reflected by the Bragg grating 300 by the thermo-optic effect of the optical waveguide 200, thereby allowing the central wavelength of the optical signal output to the other end of the optical waveguide 200 to be changed.

All of general metal heaters generating heat when electric power is applied thereto may be used as the heater 400. However, it is preferable that the heater 400 is a heater including a thin film type heating unit formed of a stack thin film made of a material selected from the group consisting of elements such as Cr, Ni, Cu, Ag, Au, Pt, Ti, and Al, and alloys thereof such as nichrome.

The direction change waveguide region 250 indicates a waveguide region changing direction of the optical signals obtained by actions of the Bragg grating 300 and the heater 400 by the predetermined angle, in an entire region of the optical waveguide 200.

The direction change waveguide region 250 may be configured so that a moving direction of the optical signals obtained by adjusting the reflection band of the Bragg grating 300 is changed three times by 60 degrees per reflection, as illustrated in FIG. 3. It may be considered that three multi-mode total reflection mirrors are used in the direction change waveguide region 250 illustrated in FIG. 3.

Here, the direction change waveguide region 250 is not limited to an example illustrated in FIG. 3, but may be configured to direction-change the optical signals obtained by the actions of the Bragg grating 300 and the heater 400 by various angles. However, in the case in which the optical signals obtained by adjusting the reflection band of the Bragg grating 300 are direction-changed by 180 degrees by the direction change waveguide region 250, there is an advantage that a volume of the external cavity type tunable wavelength laser module may be minimized.

The optical signals direction-changed by the direction change waveguide region 250 escaping from the optical waveguide 200, and some of the optical signals are transmitted through the 45-degree reflection part 500 and the others of the optical signals are reflected in the vertical upward direction by the 45-degree reflection part 500.

Here, the 45-degree reflection part 500 may be provided by bonding a separate 45-degree mirror to the other end of the optical waveguide 200 or be provided by etching the optical waveguide 200 to have an inclined surface of 45 degrees. In this case, coating is performed on a reflection surface of the 45-degree reflection part 500 so that the 45-degree reflection part 500 has a predetermined reflectivity, thereby making it possible to allow light incident to the 45-degree reflection part 500 to be reflected by or transmitted through the 45-degree reflection part 500 in a predetermined ratio.

The optical signals transmitted through the 45-degree reflection part 500 may be incident to a photodiode 700. In this case, the photodiode 700 converts the incident optical signals into electric energy to monitor an entire output change of the tunable wavelength laser module.

Meanwhile, the optical signals reflected by the 45-degree reflection part 500 to move in the vertical upward direction become the collimated light or the convergent light by the lens 600 positioned above the 45-degree reflection part 500. In detail, the optical signals becomes the collimated light in the case in which a focal length of the lens 600 is present on the 45-degree reflection part 500, and becomes the convergent light in the case in which the focal length of the lens 600 is more distant than a distance from the inclined surface of the 45 degrees to the lens 600. In this case, the optical signals condensed by the lens 600 may be incident to an optical fiber (not illustrated) positioned outside the tunable wavelength laser module. Meanwhile, a form or a focal length of the lens 600 may be variously selected in consideration of coupling loss to the optical fiber.

As described above, the external cavity type tunable wavelength laser module is characterized in that the reflection band of the Bragg grating 300 is adjusted by the thermo-optic effect of the optical waveguide 200 depending on the supply of the heat by the heater 400, such that the wavelength of the output optical signal may be changed. In this case, it is preferable that the temperature sensor 810 and the thermoelectric cooler 820 are included in the tunable wavelength laser module in order to generate a more efficient and accurate thermo-optic effect.

It is preferable that the temperature sensor 810 is provided above the optical waveguide 200 so as to measure a temperature of the optical waveguide 200 in real time to adjust a current applied to the heater 400. The temperature sensor 810 may be a general temperature sensor of which an electrical property (a voltage, a resistance, or a current amount) is changed by heat, and may be configured to include a thermistor by way of example.

It is preferable that the thermoelectric cooler 820 is provided below the optical waveguide 200 to control a temperature change of the optical waveguide 200 independently of an external temperature environment to allow the optical waveguide 200 to generate a precise thermo-optical effect. The thermoelectric cooler 820 may be configured to include a general thermoelectric element in which heat absorption is generated by a predetermined electrical signal.

It is preferable that both of the heater 400 and the thermoelectric cooler 820 may adjust a temperature at a precision less than 0.1° C., and it is preferable that the temperature sensor 810 may sense a temperature at a precision less than 0.1° C.

In addition, it is preferable that the external cavity type tunable wavelength laser module further includes a temperature control device (not illustrated) in order for stable output characteristics of the optical signal to appear independently of an external temperature environment by actions of the temperature sensor 810 and the thermoelectric cooler 820. In this case, the temperature control device is electrically connected to the heater 400, the temperature sensor 810, and the thermoelectric cooler 820 to serve to receive a signal sensed from the temperature sensor 810, thereby adjusting heat generation of the heater 400 and heat absorption of the thermoelectric cooler 820. In this case, the temperature control device may be configured to include a storage medium that is readable by a general microprocessor and a computer in which a control program is executed.

All the abovementioned optical elements constituting the external cavity type tunable wavelength laser module according to the present invention may be mounted on a TO stem 1100 for the purpose of physical support and TO-CAN packaging. It is preferable that the TO stem 1100 is made of a metal having high thermal conductivity.

The thermoelectric cooler 820 may be mounted on the TO stem 1100 using an ultraviolet-curable or thermosetting polymer resin, and the substrate 1100 positioned on the thermoelectric cooler 820 and the chip stem 110 and the optical waveguide 200 positioned on the substrate 1000 may also be mounted using an ultraviolet-curable or thermosetting polymer resin.

Meanwhile, a predetermined number of electrodes 900 may be provided at a predetermined height at the left and right of the thermoelectric cooler 820 in a form in which they penetrate through the TO stem 1100.

In the external cavity type tunable wavelength laser module according to the present invention, it is preferable that the optical waveguide 200 is a polymer optical waveguide made of a polymer and the Bragg grating 300 is also a polymer Bragg grating made of a polymer. The reason is that the polymer has a thermo-optic effect more excellent than those of other materials.

The polymer forming the optical waveguide 200 (including the claddings 210 and 220 and the core 230) or the Bragg grating 300 includes a low-loss optical polymer. It is preferable that the low-loss optical polymer includes a halogen element such as fluorine, or the like, or heavy hydrogen, in addition to elements of a general polymer, and includes a heat or ultraviolet curable functional group.

In addition, it is preferable that a thermo-optic coefficient of the polymer forming the optical waveguide 200 or the Bragg grating 300 is −9.9×10⁻⁴ to −0.5×10⁻⁴⁰ C⁻¹. It is preferable that an ultraviolet-curable acrylate-based polymer in which hydrogen is substituted by fluorine, fluorine-based polyimide, fluorinated polyacrylate, fluorinated methacrylate, polysiloxane, fluorinate-based polyarylene ether, a perfluoro cyclobutane-based polymer, or the like, is used as an example.

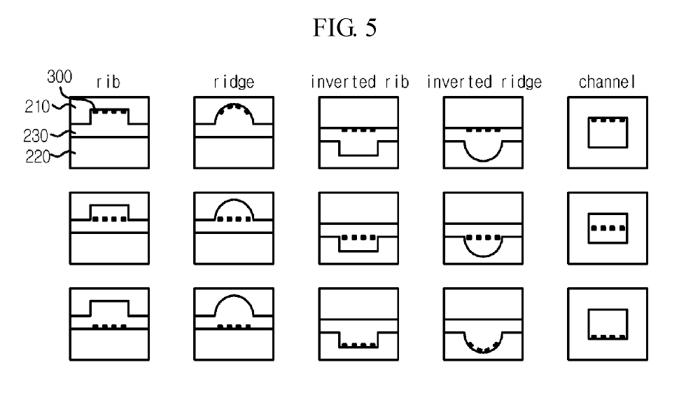

FIG. 5 is a view illustratively illustrating a structure of an optical waveguide and a position at which a Bragg grating is formed in the optical waveguide in the external cavity type tunable wavelength laser module for TO-CAN packaging according to the present invention. The optical waveguide 200 may include the claddings 210 and 220 and the core 230, and a geometric structure of the optical waveguide 200 may be a rib structure, a ridge structure, an inverted rib structure, an inverted ridge structure, or a channel structure, as illustrated in FIG. 5.

In the external cavity type tunable wavelength laser module according to an exemplary embodiment of the present invention illustrated in FIGS. 3 and 4, the channel structure among the geometric structures of the optical waveguide 200 is illustrated, and the Bragg grating 300 may be formed in the claddings 210 and 220 or the core 230 even in the case in which the optical waveguide 200 has a structure other than the channel structure.

Meanwhile, since an effective refractive index of the optical waveguide 200 is a function of a position of the Bragg grating, a thickness of the Bragg grating, an ON/OFF ratio of the Bragg grating, an order of the Bragg grating, refractive indices of polymer materials constituting the core and the claddings, and a physical shape of the core, it is not easy to theoretically predict a wavelength of an output optical signal in various structures illustrated in FIG. 5.

Therefore, it is preferable in the present invention that the optical waveguide 200 and the Bragg grating 300 are formed using the polymer, and in adjusting the effective refractive index of the optical waveguide 200, the heater 400, the temperature sensor 810, the thermoelectric cooler 820, and the temperature control device are provided to allow the temperature of the optical waveguide 200 in a portion in which the Bragg grating 300 is formed to be predictably adjusted, thereby making it possible to allow the central wavelength of the output optical signal to be easily fixed to a specific wavelength or changed.

Hereinabove, although exemplary embodiments of the present invention have been described by way of example with reference to the accompanying drawings, the present invention is not limited to these exemplary embodiments, but may be variously modified and altered by those skilled in the art without departing from the spirit and scope of the present invention.

1. An external cavity type tunable wavelength laser module comprising:
an external cavity type light source generating broadband light;
an optical waveguide to which the broadband light output from the light source is input;
a Bragg grating formed in the optical waveguide;
a heater provided above the optical waveguide in which the Bragg grating is formed and adjusting a reflection band of the Bragg grating by a thermo-optic effect;
a direction change waveguide region changing direction of optical signals obtained by the adjusted reflection band of the Bragg grating, by a predetermined angle, to output direction-changed optical signals;
a 45-degree reflection part transmitting some of the direction-changed optical signals escaping from the optical waveguide therethrough and reflecting a remainder of the direction-changed optical signals in a vertical upward direction thereby; and
a lens making the direction-changed optical signals reflected in the vertical upward direction by the 45-degree reflection part collimated light or convergent light.

2. The external cavity type tunable wavelength laser module of claim 1, wherein the direction change waveguide region is configured to direction-change the optical signals obtained by adjusting the reflection band of the Bragg grating, by 180 degrees.

3. The external cavity type tunable wavelength laser module of claim 1, further comprising a photodiode measuring power of the direction-changed optical signals transmitted through the 45-degree reflection part.

4. The external cavity type tunable wavelength laser module of claim 1, further comprising:
a temperature sensor and a thermoelectric cooler; and
a temperature control device electrically connected to the heater, the temperature sensor, and the thermoelectric cooler to receive a signal sensed from the temperature sensor, thereby adjusting heat generation of the heater and heat absorption of the thermoelectric cooler.

5. The external cavity type tunable wavelength laser module of claim 4, wherein the temperature sensor is provided above the optical waveguide, and the thermoelectric cooler is provided below the optical waveguide.

6. The external cavity type tunable wavelength laser module of claim 1, wherein the optical waveguide is a polymer optical waveguide made of a polymer.

7. The external cavity type tunable wavelength laser module of claim 6, wherein the Bragg grating is a polymer Bragg grating made of a polymer, and the polymers forming the optical waveguide and the Bragg grating include a halogen element, and include a functional group cured by ultraviolet rays or heat.

8. The external cavity type tunable wavelength laser module of claim 7, wherein a thermo-optic coefficient of the polymers forming the optical waveguide and the Bragg grating is −9.9×10⁻⁴ to −0.5×10⁻⁴⁰ C⁻¹.

9. The external cavity type tunable wavelength laser module of claim 1, wherein a geometric structure of the optical waveguide is a rib structure, a ridge structure, an inverted rib structure, an inverted ridge structure, or a channel structure.
